(19) United States
(12) Patent Application Publication
(10) Pub. No.: US 2024/0162514 A1
(43) Pub. Date: May 16, 2024

(54) APPARATUS FOR PROCESSING SENSOR DATA OF BESS AND METHOD THEREOF

(71) Applicant: AIWIN Corp., Gyeonggi-do (KR)

(72) Inventors: CANGWOO KIM, Gyeonggi-do (KR); Hyo Sub Choi, Gyeonggi-do (KR); Taeil Yun, Seoul (KR); JuHyeong Kim, Gyeonggi-do (KR)

(73) Assignee: AIWIN Corp., Gyeonggi-do (KR)

(21) Appl. No.: 18/211,445

(22) Filed: Jun. 19, 2023

(30) Foreign Application Priority Data
Jun. 17, 2022 (KR) 10-2022-0073854

(51) Int. Cl. H01M 10/48; H01M 10/42

(52) U.S. Cl. CPC H01M 10/48; H01M 10/425; H01M 2010/4271; H01M 2010/4278

(57) ABSTRACT

The present invention relates to a technique for processing sensor data in a battery energy storage system (BESS). The present invention collects sensing data of battery cells through a BMS and transmits it in a Modbus TCP manner, wherein a frame of the Modbus communication protocol includes a function code and data, and the present invention also comprises a Modbus server, wherein the function code includes information of a battery cell having a minimum or maximum sensing value and location information in a rack of batteries; and a Modbus client, which is connected to the Modbus server by the Modbus communication protocol and receives the sensing data.

### TECHNICAL FIELD

The present invention relates to a technology for processing sensor data in a battery energy storage system (BESS), and more particularly to an apparatus and method for processing sensor data in a BESS that can quickly perceive the location of a battery which is outside the range of normal operation or steady state when collecting and processing sensing data related to battery current, voltage, temperature, etc. of a BESS based on communication protocols well-known in the industry such as Modbus, DNP3.0, IEC61850, etc.

### BACKGROUND OF THE INVENTION

In recent years, battery fires and explosions of electricity storage systems (ESS) have been occurring frequently in various countries around the world. This is due to the fact that in the absence of an integrated management system, companies that manufacture each component of the ESS have created an Energy Management System (EMS), a Power Management System (PMS) and a Battery Management System (BMS) under different systems and applied them differently locally, and as a result, they have not been able to organically manage the BESS in an integrated manner. To improve this, standardization of integrated control is required to ensure that each component, such as batteries, PCS, BMS, etc. operate in a coordinated manner under a consistent management system for optimal performance. Currently, standards for ESS fire prevention and safety are being developed internationally. In this regard, research on battery management in BESS, including monitoring and predictive maintenance, is also being actively conducted.

FIG. 1 is a schematic illustration of a structure of a battery bank system in a BESS according to the prior art. It is a combination unit of batteries that is connected to a PCS and is therefore capable of charging and discharging independently, which can expand storage capacity by connecting multiple racks in parallel.

Referring to FIG. 1, a battery bank system in a BESS according to the prior art includes a plurality of N battery cells (Cells) arranged in horizontal and vertical directions on a single layer to form a module, a plurality of N such modules arranged in a plurality of N stacked structures to form a rack, and a plurality of N such racks arranged in a row to form the battery bank system. Secondary batteries that can be used as battery cells include nickel-cadmium batteries, nickel-hydrogen batteries, nickel-zinc batteries, and lithium secondary batteries. Among them, lithium rechargeable batteries are attracting attention because they are relatively free to charge and discharge, have a very low self-discharge rate, and have a high energy density compared to nickel-based rechargeable batteries.

In addition, a battery management system (BMS) is provided for battery safety management within the BESS. According to recent trends, there is a surge in research to collect sensor data measured by management items and use the data as an important indicator for condition monitoring and predictive maintenance based on the collected data. In other words, the BMS measures the current, voltage, temperature, etc. of the battery and communicates the current state of the battery to upper systems so that the battery can be used more efficiently, and triggers safety measures when an abnormality occurs, making the battery system more manageable.

In the structure of this ESS (Energy Storage System) infrastructure, it is very important to not only detect risks in real time through monitoring devices installed at battery cell installation sites that are in a warning or dangerous state, but also to build big data by continuously collecting data measured at remote analysis centers, so that ESS management methods can be made to predict and respond to risks at an early stage (i.e., warning measures, emergency operation or repair instructions to field engineers, shutdown, etc.), and various ideas are being proposed in this regard.

To operate the ESS safely, sensors that detect current, voltage, temperature, etc. are attached to the battery to collect raw data. Here, the raw data refers to the data recorded as numerical values indicating the maximum voltage, minimum voltage, maximum temperature, and minimum temperature of the battery cell.

Traditionally, Modbus TCP, a serial communication standard, is the most widely used communication protocol for data collection in the industrial field. However, in this case, sensing data related to battery cell charge and discharge data, temperature, humidity, etc. are collected or stored in semi-structured form (integers, real numbers, and characters).

Therefore, there was a problem that the Modbus client side could not intuitively analyze or judge the infrastructure structure of the ESS based on the original data. In addition, even when collecting data based on other communication protocols such as DNP3.0 or IEC61850, the challenge is that it is difficult to quickly detect battery cells in a critical state based on raw sensed data within the infrastructure of the traditional ESS. Therefore, no matter what kind of communication protocol is used, there is an urgent need to establish a data structure that enables intuitive analysis of abnormal states of ESSs to be managed through sensed data.

### CONTENTS OF THE INVENTION

### Problem to be Solved

The technical objective of the present invention is to provide an apparatus for processing sensor data of a BESS that can quickly detect the location of the battery to be treated when collecting and processing sensing data related to the battery current, voltage, temperature, etc. of the BESS based on communication protocols well-known in the industry such as Modbus, DNP3.0, or IEC61850, etc.

Another technical objective of the present invention is to provide a method for processing sensor data of a BESS that enables rapid detection of the location of the battery to be treated when collecting and processing sensing data related to the battery current, voltage, temperature, etc. of the BESS based on communication protocols well-known in the industry such as Modbus, or DNP3.0, IEC61850, etc.

### Means of Solving the Problem

To achieve the above objectives, the present invention provides an apparatus for processing sensor data of a BESS having at least one battery bank part and at least one client for detecting an abnormal situation of the BESS to be managed, wherein the battery bank part includes at least one battery rack, a sensing part for sensing a state of each of the battery racks, and a battery management system (BMS), comprising: a server for periodically receiving a sensing result data on a state of battery cells of at least one battery module disposed in the battery rack by the BMS, and transmitting the sensing result data to a client side, wherein (a) an information of the sensing result data comprises at least one of current information, voltage information, or temperature information of the battery cells; (b) a structure of the sensing result data includes an information of the battery bank part (bank), an information of the battery rack (RACK), an information of the battery module (MODULE), an information of the battery cells (CELL), and an error information (ERROR); (c) the sensing result data has the form of a series of binary sequences; and (d) the sensing result data is characterized in that the information is time stamped so that the time of occurrence of the event can be verified.

To achieve the above objectives, the present invention provides an apparatus for processing sensor data of a BESS having at least one battery bank part and a server that periodically receives sensing result data of battery cells of at least one battery module disposed in the battery rack by a battery management system (BMS) and transmits the sensing result data to a client side, wherein the battery bank part includes at least one battery rack, a sensing part for sensing a state of each of the battery racks, and the BMS, comprising: at least one the client that periodically requests the sensing result data from the server, and receives the sensing result data received from the server to detect and process whether an abnormal situation occurs in the BESS to be managed, wherein (a) an information of the sensing result data comprises at least one of current information, voltage information, or temperature information of the battery cells; (b) a structure of the sensing result data includes an information of the battery bank part (bank), an information of the battery rack (RACK), an information of the battery module (MODULE), an information of the battery cells (CELL), and an error information (ERROR); (c) the sensing result data has the form of a series of binary sequences; and (d) the sensing result data is characterized in that the information is time stamped so that the time of occurrence of the event can be verified.

To achieve the above objectives, the present invention provides a method for processing sensor data of a BESS having at least one battery bank part and at least one client for detecting an abnormal situation of the BESS to be managed, wherein the battery bank part includes at least one battery rack, a sensing part and a battery management system (BMS) for detecting a state of each battery rack, comprising: periodically receiving, by the server, a sensing result data from the BMS about battery cells of at least one battery module disposed in the battery rack; and transmitting the sensing result data by the server to the client, wherein (a) an information of the sensing result data comprises at least one of current information, voltage information, or temperature information of the battery cells; (b) a structure of the sensing result data includes an information of the battery bank part (bank), an information of the battery rack (RACK), an information of the battery module (MODULE), an information of the battery cells (CELL), and an error information (ERROR); (c) the sensing result data has the form of a series of binary sequences; and (d) the sensing result data is characterized in that the information is time stamped so that the time of occurrence of the event can be verified.

To achieve the above objectives, the present invention also provides a method for processing sensor data of a BESS having at least one battery bank part and a server, wherein the battery bank part includes at least one battery rack, a sensing part for sensing a state of each of the battery racks, and a battery management system (BMS), wherein the server periodically receives sensing result data of battery cells of at least one battery module disposed in the battery rack by the BMS and transmits the sensing result data to a client side, comprising: periodically requesting the sensing result data by the client to the server side; and receiving the sensing result data from the server by the client and then detecting and processing whether an abnormal situation occurs in the BESS to be managed, wherein (a) an information of the sensing result data comprises at least one of current information, voltage information, or temperature information of a battery cell; (b) a structure of the sensing result data comprises an information of the battery bank (BANK), an information of the battery rack (RACK), and an information of the battery module (MODULE), an information of the battery cells (cell), and an error information (error); (c) the sensing result data is in the form of a series of binary sequences; and (d) the sensing result data is time stamped to enable verification of the time of occurrence of the event.

It is further characterized in that the sensing result data is data transmitted and received based on any one of a Modbus communication protocol (Modbus TCP), a DNP 3.0 protocol, or an IEC 61850 protocol.

Further, the sensing result data is transmitted and received according to a frame of the Modbus communication protocol (Modbus TCP) comprising a function code area and a data area, wherein the function code area includes an information of the battery cell in which the minimum or maximum sensing value is stored in the random battery rack and the location information. The term “error” includes not only when the sensor itself fails (defects), but also when the resultant value detected by the sensor during normal operation deviates from a predetermined State of Safety (SoS) indicator.

Furthermore, under the 16 bits of data structure illustrated in FIG. 3, the data area is characterized in that the bit areas are allocated to include 2 bits of bank information, 4 bits of rack information, 5 bits of module information, 4 bits of battery cell information, and 1 bit of error information, respectively. As a result, the 1 bit of “error” information in the sensing result data simply indicates whether the measured value has deviated from the normal state. In another embodiment, the bank information, the rack information, the module information, the cell information, and the error information areas can be expanded, if necessary, to extend the total data area to 32 bits or more and can be modified to further convey information about which sensor the error occurred. In another embodiment, the data area can be further expanded as needed, such as to 64 bits, 128 bits, etc., instead of being limited to 32 bits, to include more specific information on which sensor the error occurred and in what context it occurred.

Further, the data area further comprises binary values for the bank, the rack, the module, battery cell, and the error information arranged in a row and then replaced by a decimal integer value, wherein the decimal integer value is arranged by raw.

### Effects of the Invention

The apparatus and method for processing sensor data in a BESS according to the present invention have the following effects.

First, it has the effect of quickly detecting the position of the battery associated with the sensor data values (battery voltage, temperature, etc.) of the BESS in an environment communicating based on Modbus TCP. In particular, when expressing the sensor data, it is possible to quickly analyze out the location of the battery charging/discharging voltage by changing the value from an integer value to a value converted by a distinguished binary operation.

Second, when the sensor data processing technology according to the present invention is applied to the firmware of a BMS or EMS of a BESS or to a big data collection system, data scientists analyzing the source data can make quick predictions and field engineers can take quick actions.

Third, it has the effect of building an efficient BESS monitoring system by systematizing the sensor modules of the BESS based on the location information collected.

### BRIEF DESCRIPTION OF THE DRAWINGS

FIG. 1 is a structure of a battery bank system in a BESS according to the prior art.

FIG. 2 is a block diagram of a sensor data processing unit of a battery energy storage system according to an embodiment of the present invention.

FIG. 3 is a diagram illustrating a frame structure of ModBus TCP according to an embodiment of the present invention.

FIG. 4 is a diagram illustrating a data structure according to an embodiment of the present invention.

FIG. 5 is a flowchart of a sensor data processing method of a BESS according to an embodiment of the present invention.

### DETAILED DESCRIPTION OF EMBODIMENTS

Hereinafter, embodiments of the present invention will be described in detail with reference to the accompanying drawings. First of all, in assigning reference numerals to the components in each drawing, the same components are given the same numeral as far as possible, even if they are shown in different drawings, and it is noted that the accompanying drawings are for the purpose of illustration only, and their geometries and relative dimensions may be exaggerated or omitted. In addition, in describing the invention, if it is determined that a detailed description of the relevant disclosed configuration or function would be self-evident to those skilled in the art or would obscure the essence of the invention, the detailed description is omitted. In the following description, when a component is said to “include” another component, it means that it may include additional components in addition to those listed, unless the contrary is specifically stated. The terms “part,” “unit,” “device,” “module,” and the like in the specification refer to a unit that performs at least one function or operation, which may be implemented in hardware or software or a combination of hardware and software. Also, when a part is said to be electrically connected to another part, this includes direct connections as well as connections with other configurations in between. On the other hand, when a component is said to be “directly connected” or “directly coupled” to another component, it is to be understood that there is no other component in between. On the other hand, terms containing ordinal numbers, such as first, second, etc., may be used to describe various components, which may be used for the purpose of distinguishing one component of the same type from another.

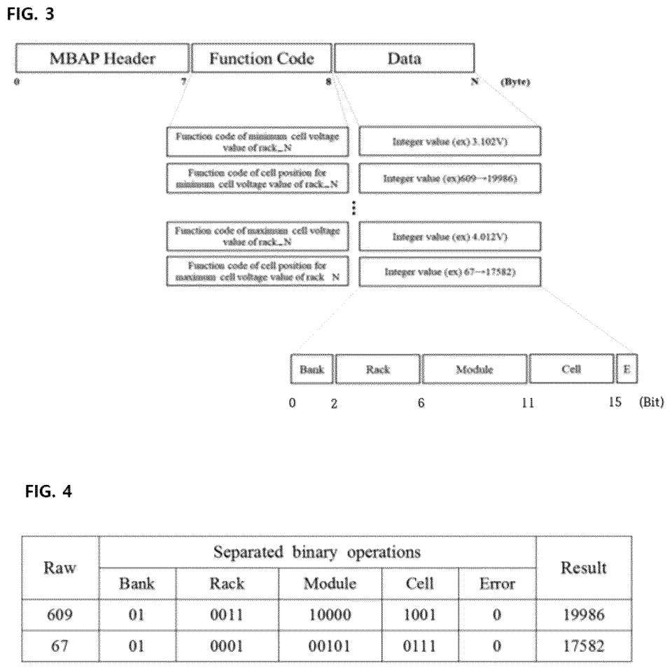

FIG. 2 is a block diagram of a BESS according to one embodiment of the present invention, FIG. 3 is a structure diagram of a frame of Modbus TCP according to one embodiment of the present invention, and FIG. 4 is a structure diagram of data according to one embodiment of the present invention. The communication protocol applicable to the BESS of the present invention can be any protocol in principle, but the Modbus, the DNP3.0, the IEC61850, etc. are preferred for rational construction of the integrated system. Hereinafter, as a preferred embodiment of the present invention, a sensor data processing technology of the BESS that enables the location of the battery to be quickly detected when collecting and processing sensing data related to the battery current or voltage, temperature, humidity, illumination, abnormal gas detection, etc. of the BESS is described, focusing on the contents based on Modbus-TCP.

ModBus-TCP is a communication protocol often used in the field of industrial fieldbus and is a communication method designed for interfacing between higher-level devices and lower-level devices on a TCP/IP network. For normal data communication between a master (Client) and a slave (Server), data packets that conform to the ModBus-TCP frame structure must be transmitted.

On the other hand, application examples based on other protocols such as the DNP3.0, the IEC61850, etc. are self-evident and repetitive for those having ordinary skills in the field as described below, so they are omitted without further explanation. However, the ModBus protocol does not consider time data in its communication system, so as mentioned above, additional measures are required for data visual synchronization. On the other hand, if the data is transmitted by the DNP3.0 protocol or the IEC 61850 standard-based communication, which are protocols that can transmit data with time stamps, which are widely used in power systems, the incoming PCS and BMS data is stored in the database (DB) in the order of the time stamps of individual data, so it is possible to clearly verify the data even if a problem occurs afterwards. In addition, to provide a data map for smooth operation and management of the entire BESS facility, IEC 61850 recommends using the standard LN (Logical Node) format.

Referring to FIG. 2, a BESS 100 according to one embodiment of the present invention includes at least one battery bank 110; a power control system (PCS) 120; a Modbus server 130; and a Modbus client 140. In addition, a time synchronization device (e.g., SNTP server, not shown) is further provided to ensure time coherence of various operation data of the PMS, PCS, and battery, which are the main facilities comprising the BESS.

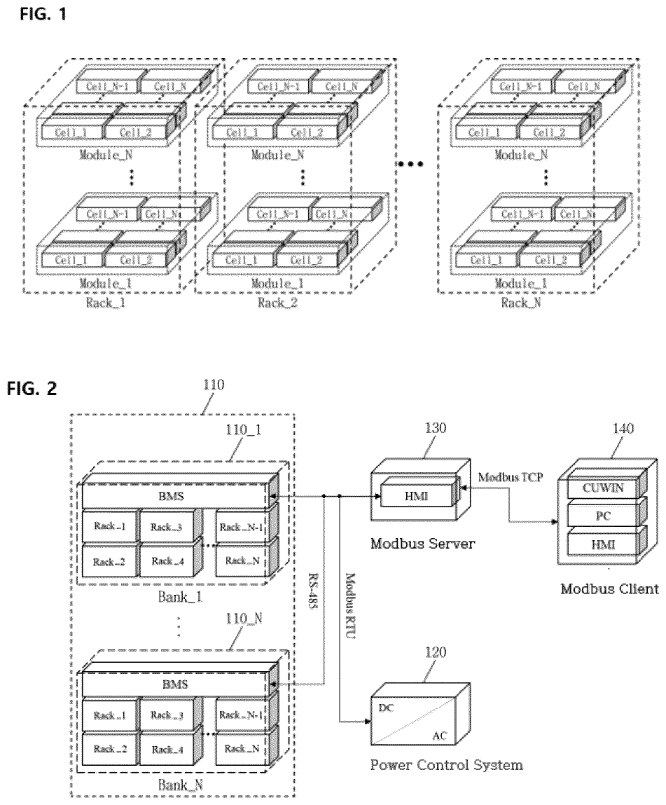

The battery bank 110 of FIG. 2 includes a plurality of N battery bank parts (110_1˜110_N). The battery bank parts (110_1˜110_N) are arranged in vertical and horizontal directions, respectively, and each of the battery bank parts (110_1˜110_N) includes a plurality of N battery racks (Rack_1˜Rack_N) and a battery management system (BMS) for managing them, and each of the plurality of N battery racks (Rack_1˜Rack_N) is connected with the BMS. Each of said battery racks (Rack_1˜Rack_N) has a structure as shown in FIG. 1. That is, each of said battery racks (Rack_1˜Rack_N) includes a plurality of N battery modules (Module_1˜Module_N) stacked in a vertical direction. Further, each of the battery modules (Module_1˜Module_N) includes a plurality of N battery cells (Cell_1-Cell_N) arranged in the row and column directions, respectively.

The battery management system (BMS) is responsible for optimally managing each battery cell (Cell_1˜Cell_N) deployed as described above to improve energy efficiency and extend its lifespan. For example, the BMS monitors the voltage, current, and temperature of the battery cells in real time to prevent excessive charging and discharging in advance according to the State of Safety (SoS) indicators such as maximum voltage, minimum voltage, maximum temperature, minimum temperature, current, voltage imbalance, and temperature imbalance collected by the BMS. In addition, a gas sensor to detect gas emitted due to thermal runaway of the battery or abnormal overheating of other devices (or their parts) and an aspirated smoke detector (ASD) to detect smoke generated in abnormal situations such as an internal fire or a fire in a nearby area are equipped and monitored in real time to improve the safety and reliability of battery management by inducing a rapid initial response even in the event of an accident.

The battery bank 110 is provided with a sensing part (not shown in the drawing). The sensing part comprises a plurality of sensing units for detecting battery data and environmental data for each battery rack (Rack_1 to Rack_N), and the sensing units may include temperature sensors, humidity sensors, gas sensors, smoke detectors, voltage sensors, and current sensors.

The temperature sensor measures the temperature of the battery cells (Cell_1˜Cell_N) or the temperature of the place where the battery is stored at a predetermined time interval and provides the result. Through this temperature measurement, if the temperature of the battery is too high or too low outside the normal operating range, it is necessary to warn or stop the system operation accordingly.

The humidity sensor measures the humidity in the area where the battery cells (Cell_1 to Cell_N) are stored and is used to activate the heating or cooling system if the humidity is too high or too low.

The gas sensor is intended to detect gases emitted by the battery cells (Cell_1 to Cell_N) prior to the explosion of the battery cells (Cell_1-Cell_N) at the location where the battery cells (Cell_1 to Cell_N) are stored. This invention may further include an aspirating smoke detector (ASD) for early detection of thermal runaway. This increases the likelihood of an early successful action in the event of a fire incident, before the smoke and corrosive gases can cause adverse effects in the early stages.

On the other hand, as mentioned above, instead of installing the necessary sensors separately, it is possible to use a complex sensor made by integrating the necessary sensors. For reference, Korean Patent Publication No. 10-2021-0036545 (5 Apr. 2021) discloses a complex sensor technology that can detect temperature, gas, humidity, and fine dust in real time. This complex sensor is designed to monitor the occurrence of fire by transmitting an alarm signal when the temperature, gas, humidity, and fine dust measurement data in the space where the ESS is installed exceeds the preset values.

The voltage sensor measures the voltage of each battery cell (Cell_1 to Cell_N), and the current sensor measures the battery current of each battery cell (Cell_1 to Cell_N).

The power conditioning system (PCS) 120 is a device that performs the functions of an inverter that converts DC power generated by the secondary battery to AC and a converter that converts AC power from the grid to DC and performs charging and discharging of the battery cells (Cell_1-Cell_N). In other words, the power conditioning system 120 converts the alternating current voltage to the battery storage voltage or converts the battery storage voltage to the commercial voltage (alternating current) that is actually used.

The Modbus server 130 receives various information from the PCS or BMS to enable real-time monitoring of the BESS, and performs the functions of a PMS (Power Management System) that manages the overall power by controlling the amount of charge and discharge power in reflection of power system frequency fluctuations or the requirements of the higher management system, and an EMS (Energy Management System) that integrates all the information that can be collected and implements it on the control screen for system monitoring and overall system effectiveness analysis. For this purpose, the Modbus server 130 is electrically connected to the PCS 120 to monitor the power demand status of the battery and can also communicate with other systems.

The Modbus server 130 monitors the status of the battery cells (Cell_1˜Cell_N) disposed in each battery rack (Rack_1˜Rack_N) through the battery management system (BMS) of each battery bank (110_1˜110_N), and controls the operation of the power conditioning system 120 in consideration of the monitoring results to discharge or charge a plurality of battery cells (Cell_1-Cell_N) into the power system.

In addition, the Modbus server 130 collects sensing data (battery data and environmental data) related to the voltage, temperature, etc. of the battery cells of the battery energy storage system (BESS) through the battery management system (BMS). The Modbus server 130 is connected to the Modbus client 140 via the Modbus communication protocol (Modbus TCP) and can provide the collected sensing data to the Modbus client 140.

The frame structure of the ModBus-TCP connecting the ModBus server 130 and the ModBus client 140 is illustrated in FIG. 3, and in particular, the use of the data structure illustrated in FIG. 4 enables the location of battery cells requiring systematic warning or emergency action to be quickly identified based on function code and data.

The top portion of FIG. 3 illustrates the internal structure of a Modbus TCP frame, including the ModBus Application Protocol (MBAP) Header, Function Code, and Data. The MBAP is 7 bytes in length and contains the following information.
Transaction ID [2 Bytes]: The master (Client) increases the value by 1 at the beginning of communication from the initial 0x0000 value, and the slave (Server) copies and uses the value as it is. This is the part that checks whether the query and response are executed in pairs.
Protocol ID [2 Bytes]: As a protocol ID, ModBus-TCP uses a fixed value of 0x0000.
Length [2 Bytes]: Indicates the length from the position of the Length field to the end of the frame. In other words, it indicates the number of bytes from Unit ID to the end of Data.
Unit ID [1 Byte]: This is information to identify a Slave that is connected to a communication line other than TPC/IP.

The middle portion of FIG. 3 includes a function code for reading information of the battery cell, such as a minimum or maximum voltage (or temperature) information, and a position of the battery cell, such as an Integer value, from an arbitrary battery rack (e.g., Rack_N). The function code is an instruction set code provided by the ModBus protocol. The function code can be used to read or write values from the slave memory (Coil, Register). The values from Function Code 1 to Function Code 127 are used. As shown in [Table 1] below, the ModBus data model is divided into four types based on input and output and bit-by-bit access and word-by-word access. The data model can be used as four data blocks by specifying a data block for each type of data, or it can be used as two data blocks divided into bit area and word area. TCPport is divided into two data memories: 16-bit word area (Resisters) and bit area (Coils). The memory here refers to the memory of the slave (server), and the master (client) can read or change the memory of the slave (server) to the desired value using the above function code. In other words, the function code determines which memory to access and which operation to perform (read, write).

TABLE 1

| | | Accss | | |
|---|---|---|---|---|
| Memor | Data Model | Frame | Read/Writ | Description |
| Coil | Discrete Input | Bit | Read | Can Read Memory on Upper device |
| Coil | Coils | Bit | Read/Writ | Can Read/Write Memory on Upper |
| | | | | device |
| Register | Input Register | 16-bit Word | Read | Can Read Memory on Upper device |
| Register | Holding | 16-bit Word | Read/Writ | Can Read/Write Memory on Upper |
| | Register | | | device |

In a preferred embodiment of the present invention, assuming a conventionally scaled BESS 100 environment having 4 or fewer battery bank parts (110_1˜110_N); 16 or fewer racks (Rack_1˜Rack_N) in each battery bank part; 32 or fewer modules (Module 1˜Module N) in each rack; and 16 or fewer battery cells (Cell_1˜Cell_N) in each module, the bottom portion of FIG. 3 shows an integer value of Data as 16 bits.

The structure of the data may vary depending on the function code, and basically has the form of Start Address, Length, Byte Count, and Data as shown below.
Start Address [2 Bytes]: Indicates the starting address of the memory to be accessed. If it is expressed as 2 Byte, it is the highest byte priority.
Length [2 Bytes]: Indicates the length to ‘read’ or ‘write’ the value from the start address.
Byte Count [1 Bytes]: Indicates the number of bytes of memory data according to the request and response. In other words, it is the number of bytes of memory data to be ‘read’ or ‘written’.
DATA [N Byte]: Indicates the value of memory data according to Request and Response. In other words, it is the memory value to be read or written.

In this embodiment, 2 bits are allocated for bank information, 4 bits for rack information, 5 bits for module information, 4 bits for battery cell information, and 1 bit for error information, respectively, to represent the information as a binary value, in accordance with the general scale of BESS (100) environment as described above.

Table 2 below shows an example of the structure information by ESS bank site, for example, bank site 1 has 8 racks, 16 modules per rack, and 12 battery cells per module.

TABLE 2
# Examples of structure information for each ESS site

| | |
|---|---|
| ESS_SITES_INFO = { | |
| “ESS_Operating_Site1”: { | |
| “banks”: [ | |
| { | |
| “rack_count”: 8, | # The number of Racks |
| “module_per_rack”: 16, | # The number of Modules per Rack |
| “cell_per_module”: 12 | # The number of Cells per Mmodule |
| } | |
| ], | |
| }, | |
| “ESS_Operating_Site2”: { | |
| “banks”: [ | |
| { | |
| “rack_count”: 9, | # The number of Racks |
| “module_per_rack”: 10, | # The number of Modoles per Rack |
| “cell_per_module”: 12 | # The number of Cells per Mmodole |
| }, | |
| { | |
| “rack_count”: 8, | # The number of Racks |
| “module_per_rack”: 14, | # The number of Modules per Rack |
| “cell_per_module”: 12 | # The number of Cells per Mmodule |
| } | |
| ], | |
| }, | |
| “ESS_Operating_Site3”: { | |
| “banks”: [ | |
| { | |
| “rack_count”: 12, | # The number of Racks |
| “module_per_rack”: 17, | # The number of Modules per Rack. |
| “cell_per_module”: 12 | # The number of Cells per Mmodole |
| } | |
| ], | |
| } | |
| } | |

Table 3 below illustrates the process of converting a binary number to a decimal number, or a decimal cell number to a binary number.

TABLE 3

```
# Converting binary to decimal
  def binary_to_decimal(binary_string):
    return int(binary_string, 2)
# Converting cell number in decimal to binary
  def convert_to_binary(location, bits):
    binary_str = “{0:b}”,format(location)
    while len(binary_str) < bits:
      binary_str = “0” + binary_str
    return binary_str
```

Table 4 below is an example of the process of retrieving location information based on cell number and generating converted values.

TABLE 4
# Retrieving location information based on cell number, and
generating conversion value and processing it

```
def encode_location_and_convert_cell_num(sites, site, cell_number,
error_code:
  # Get the site data
  site_data = sites[site]
  bank_data = site_data[ [symbol] banks [symbol] ][0]
  total_racks = bank_data{ [symbol] rack_count [symbol] ]
  total_modules = bank_data[ [symbol] module_per_rack [symbol] ]
  total_cells = bank_data[ [symbol] cell_per_module [symbol] ]
  cells_per_rack = total_modules [symbol]  total_cells
  cells_per_bank = total_racks [symbol]  cells_per_rack
  bank_number = (cell_number - 1) // cells_per_bank + 1
  remainder = (cell_number - 1) % cells_per_bank
  rack_number = remainder // cells_per_rack + 1
  remainder = remainder % cells_per_rack
  module_number = remainder // total_cells + 1
  cell_number = remainder % total_cells + 1
  bank_binary = convert_to_binary(bank_number, 2)
  rack_binary = convert_to_binary(rack_number, 4)
  module_binary = convert_to_binary(module_number, 5)
  cell_binary = convert_to_binary(cell_number, 4)
  error_binary = convert_to_binary(error_code, 1)
  combined_binary = bank_binary + rack_binary + module_binary +
cell_binary + error_binary
  return binary_to_decimal(combined_binary) [symbol]
indicates data missing or illegible when filed
```

Table 5 below is an example of processing the return of cell information based on a conversion value.

```
TABLE 5
# Processing the return of cell information from the conversion value
def decode_from_encode_data(value):
    binary_string = [symbol] (0:b) [symbol] .format(value).zfill(16)
    # Decode each field from the binary string
    bank = int(binary_string[:2], 2)
    rack = int(binary_string[2:6], 2)
    module = int(binary_string[6:11], 2)
    cell = int(binary_string[11:15], 2)
    error = int(binary_string[-1])
    return {
        “bank”: bank,
        “racck”: rack,
        “module”: module,
        “cell”: cell,
        “error”:error,
    } [symbol]
indicates data missing or illegible when filed
```

Table 6 below is an example of processing the return of cell information based on a conversion value.

TABLE 6
# Processing conversion to cell number based on location information

```
def restore_location(decoded_location, site_data);
  bank_data = site_data[ [symbol] banks [symbol] ][0]
  total_racks = bank_data[ [symbol] rack_count [symbol] ]
  total_modules = bank_data[ [symbol] module_per_rack [symbol] ]
  total_cells = bank_data[ [symbol] cell_per_module [symbol] ]
  cells_per_rack = total_modules [symbol]  total_cells
  cells_per_bank = total_racks [symbol]  cells_per_rack
  # Calculate the original cell number
  cell number = ((decoded_location[“bank”] - 1) [symbol]  cells_per_bank +
              (decoded_location[“rack”] - 1) [symbol]  cells_per_rack +
              (decoded_location[“module”] - 1) [symbol]  total_cells +
              decoded_location[“cell”])
  return cell_number [symbol]
indicates data missing or illegible when filed
```

Table 7 below is an example of a process that (1) presents the number ‘609’ of an arbitrary warning target cell, (2) generates location information and conversion value (meaning sensing result data) based on the cell number, (3) enables intuitive and quick detection of the battery location by looking up the cell information based on the conversion value, and (4) processes to return to the original cell number information (609) based on the cell location information.

```
TABLE 7
# Providing the cell number to be warned
  warn_cell_number = 609
# Retrieving location information based on cell number and generating conversion value
  coverted_cell_number = encode_location_and_convert_cell_num(sites [symbol] ESS_SITES_INFO,
                                                      site [symbol] ESS_Operating_Site1, [symbol]
                                                      cell_number [symbol] warn_cell_number,
                                                      error_code [symbol] 0)
print( [symbol] Warning cell to encoding [symbol] , warn_cell_number, [symbol] (warning cell number) to [symbol]
      coverted_cell_number, [symbol] (encode cell number) [symbol] )
# Retrieving information of the warning cell based on the conversion value
  cell_location = decode_from_encode_data(value=coverted_cell_number)
  print( [symbol] warning cell location : [symbol] , cell_location)
# Restoring to original cell number based on cell location information
  cell_num = restore_location(decoded_location=cell_location,
                        site_data [symbol] ESS_SITES_INFO[ [symbol] ESS_Operating_Site1 [symbol] ])
print( [symbol] Convert cell location info to origional cell number [symbol] , cell_num , [symbol] (waring cell
number) [symbol] ) [symbol]
indicates data missing or illegible when filed
```

[symbol]

In other words, by obtaining a binary sequence of 16 bits (i.e., 01, 0100, 00011, 1001, 0) from the encoding cell number “20594” corresponding to the sensing result data of the warning target cell 609, it can be intuitively recognized that the bank information “bank” is 1, the rack information “rack” is 4, the module information “module” is 3, the battery cell information “cell” is 9, and the error information “error” is “0”.

The structure of the above data is described with reference to FIG. 4, which illustrates the result value of a separated binary operation indicating the position of a battery cell as an example. The method of separated binary operations is to convert a decimal integer value representing a position sequence of a battery into a decimal value by integrating binary numbers separated into bank information, rack information, module information, cell information, and error information. In the case of Raw 609, bank is represented as ‘01’, rack is represented as ‘0011’, module is represented as ‘10000’, cell is represented as ‘1001’, and error is represented as ‘0’, and the binary value ‘0100111000010010’, which is arranged in a row, is replaced with a decimal integer value to represent the result value ‘19986’.

As another example, for Raw 67, bank is represented by ‘01’, rack by ‘0001’, module by ‘00101’, battery cell by ‘0111’, and error by ‘0’, and the binary value ‘0100010010101110’ in a row of them is replaced by an integer value in decimal, resulting in the value ‘17582’.

The Raw item is information that the manager of the BESS can use as a reference to recognize the location of the battery cell.

The Modbus client 140 is connected to the Modbus server 130 by a Modbus TCP method as described above and transmits and outputs data in the frame structure as described above. Therefore, the manager of the BESS of the Modbus client 140 can quickly recognize the location of the battery cell, i.e., the battery cell that is in a dangerous state, based on the function code and data as described above, so that it is possible to immediately repair or take safety measures.

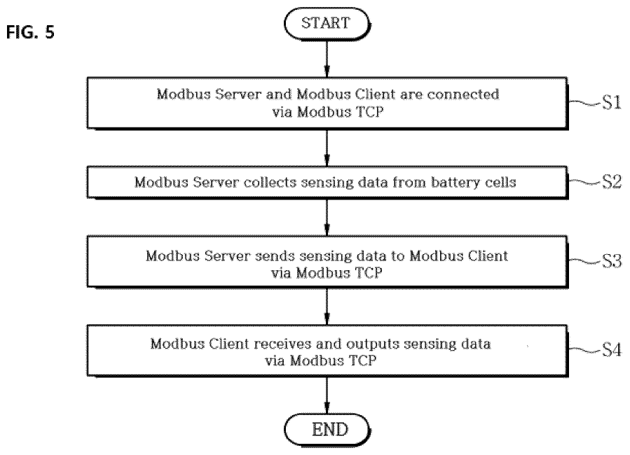

Meanwhile, FIG. 5 is a flowchart of a sensor data processing method of a BESS according to one embodiment of the present invention.

Referring to FIG. 5, a sensor data processing method of a BESS according to one embodiment of the present invention includes a step (S1) in which a Modbus server and a Modbus client are connected by a Modbus TCP method; a step (S2) in which sensing result data of a battery cell (such as battery data and environmental data) is collected by the Modbus server; a step (S3) in which the Modbus server transmits the sensing result data to the Modbus client by a Modbus TCP method; and a step (S4) in which the Modbus client (140) receives and outputs the sensing result data by a Modbus TCP manner, wherein (a) the sensing result data comprises data relating to at least one of current, voltage or temperature of the battery cell, (b) the sensing result data comprises battery bank information (bank), battery rack information (rack) and battery module information (module), battery cell information (cell), and error information (error), (c) the sensing result data is transmitted in the form of a series of binary sequences that have been binary converted, and (d) the sensing result data is time stamped to enable verification of the time of occurrence of the event.

First, the Modbus server 130 is connected to the Modbus client 140 via the Modbus TCP connection (S1). A description of the Modbus TCP method can be found in the foregoing description and is omitted to avoid repetition.

The Modbus server 130 receives sensing data of the battery racks (Rack_1˜Rack_N) from the sensing part of the battery bank 110 through the battery management system (BMS), and collects sensing data related to the current, voltage, temperature, etc. of the battery cells based on the sensing data (S2).

The Modbus server 130 transmits the sensing data to the Modbus client 140 via Modbus TCP. Here, the Modbus TCP frame includes an MBAP Header, a Function Code, and Data. The function code includes the information of the battery cell where the minimum or maximum voltage (or temperature) is stored and the position of the battery cell in the battery rack (e.g., Rack_N). Further, the value of the data (Integer value) may be represented by a conventional size of 16 bits. In this case, the bank information (bank), rack information (rack), module information (module), battery cell information (cell), and error information (error) for the above data values can be represented by binary values of 2 bits, 4 bits, 5 bits, 4 bits, and 1 bit, respectively. If necessary, it is possible to expand the total data area to 32 bits, 64 bits, etc., while increasing the number of bits allocated for information about bank, rack, module, cell, and error (S3).

The Modbus client 140 receives and outputs the sensing data from the Modbus server 130 via Modbus TCP (S4).

Thus, a person managing the BESS can more conveniently and quickly check the location of the cell having a maximum/minimum voltage, the location of a module having a maximum/minimum temperature, etc. based on the location information.

The order in which each of the above steps (S1 to S4) is performed is not particularly limited and may be performed in any order as required.

The foregoing has been described and illustrated with reference to a preferred embodiment to exemplify the technical ideas of the present invention. However, it will be well understood by those skilled in the art that the invention is not limited to the construction and operation as hereinbefore shown and described, and that various changes and modifications are possible without departing from the scope of the technical idea of the invention. All such suitable changes and modifications and equivalents are therefore to be considered as falling within the scope of the invention.

### DESCRIPTION OF SYMBOLS

110: Battery bank, 110_1-110_N: Battery bank part, 120: Power Control System, 130: Modbus server, 140: Modbus client, BMS: Battery Management System, Cell_1-Cell_N: Battery cell

What is claimed is:

1. An apparatus for processing sensor data of a BESS having at least one battery bank part and at least one client for detecting an abnormal situation of the BESS to be managed, wherein the battery bank part includes at least one battery rack, a sensing part for sensing a state of each of the battery racks, and a battery management system (BMS), comprising:
a server for periodically receiving a sensing result data on a state of battery cells of at least one battery module disposed in the battery rack by the BMS, and transmitting the sensing result data to a client side,
wherein (a) an information of the sensing result data comprises at least one of current information, voltage information, or temperature information of the battery cells; (b) a structure of the sensing result data includes an information of the battery bank part (bank), an information of the battery rack (RACK), an information of the battery module (MODULE), an information of the battery cells (CELL), and an error information (ERROR); (c) the sensing result data has the form of a series of binary sequences; and (d) the sensing result data is characterized in that the information is time stamped so that the time of occurrence of the event can be verified.

2. An apparatus for processing sensor data of claim 1, wherein the sensing result data is transmitted or received data based on any one of a Modbus communication protocol (Modbus TCP), a DNP 3.0 protocol, or an IEC 61850 protocol.

3. An apparatus for processing sensor data of claim 2, wherein the sensing result data is transmitted and received in accordance with a frame of the Modbus communication protocol (Modbus TCP) comprising a function code region and a data region, wherein the function code region includes an information of a battery cell having a minimum or maximum sensing value stored therein and an information of a location of the battery cell.

4. An apparatus for processing sensor data of claim 3, wherein the data area is allocated bit areas to include 2 bits of bank information, 4 bits of rack information, 5 bits of module information, 4 bits of battery cell information, and 1 bit of error information, respectively.

5. An apparatus for processing sensor data of claim 4, wherein the data area further comprises binary values for the bank information, the rack information, the module information, the battery cell information, and the error information arranged in a row and then replaced by a decimal integer value, wherein the decimal integer value is arranged by raw.

6. An apparatus for processing sensor data of a BESS having at least one battery bank part and a server that periodically receives sensing result data of battery cells of at least one battery module disposed in the battery rack by a battery management system (BMS) and transmits the sensing result data to a client side, wherein the battery bank part includes at least one battery rack, a sensing part for sensing a state of each of the battery racks, and the BMS, comprising:
at least one the client that periodically requests the sensing result data from the server, and receives the sensing result data received from the server to detect and process whether an abnormal situation occurs in the BESS to be managed,
wherein (a) an information of the sensing result data comprises at least one of current information, voltage information, or temperature information of the battery cells; (b) a structure of the sensing result data includes an information of the battery bank part (bank), an information of the battery rack (RACK), an information of the battery module (MODULE), an information of the battery cells (CELL), and an error information (ERROR); (c) the sensing result data has the form of a series of binary sequences; and (d) the sensing result data is characterized in that the information is time stamped so that the time of occurrence of the event can be verified.

7. An apparatus for processing sensor data of claim 6, wherein the sensing result data is transmitted or received data based on any one of a Modbus communication protocol (Modbus TCP), a DNP 3.0 protocol, or an IEC 61850 protocol.

8. An apparatus for processing sensor data of claim 7, wherein the sensing result data is transmitted and received in accordance with a frame of the Modbus communication protocol (Modbus TCP) comprising a function code region and a data region, wherein the function code region includes an information of a battery cell having a minimum or maximum sensing value stored therein and an information of a location of the battery cell.

9. An apparatus for processing sensor data of claim 8, wherein the data area is allocated bit areas to include 2 bits of bank information, 4 bits of rack information, 5 bits of module information, 4 bits of battery cell information, and 1 bit of error information, respectively.

10. An apparatus for processing sensor data of claim 9, wherein the data area further comprises binary values for the bank information, the rack information, the module information, the battery cell information, and the error information arranged in a row and then replaced by a decimal integer value, wherein the decimal integer value is arranged by raw.

11. A method for processing sensor data of a BESS having at least one battery bank part and at least one client for detecting an abnormal situation of the BESS to be managed, wherein the battery bank part includes at least one battery rack, a sensing part and a battery management system (BMS) for detecting a state of each battery rack, comprising:
periodically receiving, by the server, a sensing result data from the BMS about battery cells of at least one battery module disposed in the battery rack; and
transmitting the sensing result data by the server to the client,
wherein (a) an information of the sensing result data comprises at least one of current information, voltage information, or temperature information of the battery cells; (b) a structure of the sensing result data includes an information of the battery bank part (bank), an information of the battery rack (RACK), an information of the battery module (MODULE), an information of the battery cells (CELL), and an error information (ERROR); (c) the sensing result data has the form of a series of binary sequences; and (d) the sensing result data is characterized in that the information is time stamped so that the time of occurrence of the event can be verified.

12. A method for processing sensor data of claim 11, wherein the sensing result data is transmitted or received data based on any one of a Modbus communication protocol (Modbus TCP), a DNP 3.0 protocol, or an IEC 61850 protocol.

13. A method for processing sensor data of claim 12, wherein the sensing result data is transmitted and received in accordance with a frame of the Modbus communication protocol (Modbus TCP) comprising a function code region and a data region, wherein the function code region includes an information of a battery cell having a minimum or maximum sensing value stored therein and an information of a location of the battery cell.

14. A method for processing sensor data of claim 13, wherein the data area is allocated bit areas to include 2 bits of bank information, 4 bits of rack information, 5 bits of module information, 4 bits of battery cell information, and 1 bit of error information, respectively.

15. A method for processing sensor data of claim 14, wherein the data area further comprises binary values for the bank information, the rack information, the module information, the battery cell information, and the error information arranged in a row and then replaced by a decimal integer value, wherein the decimal integer value is arranged by raw.

16. A method for processing sensor data of a BESS having at least one battery bank part and a server, wherein the battery bank part includes at least one battery rack, a sensing part for sensing a state of each of the battery racks, and a battery management system (BMS), wherein the server periodically receives sensing result data of battery cells of at least one battery module disposed in the battery rack by the BMS and transmits the sensing result data to a client side, comprising:
periodically requesting the sensing result data by the client to the server side; and
receiving the sensing result data from the server by the client and then detecting and processing whether an abnormal situation occurs in the BESS to be managed,
wherein (a) an information of the sensing result data comprises at least one of current information, voltage information, or temperature information of a battery cell; (b) a structure of the sensing result data comprises an information of the battery bank (BANK), an information of the battery rack (RACK), and an information of the battery module (MODULE), an information of the battery cells (cell), and an error information (error); (c) the sensing result data is in the form of a series of binary sequences; and (d) the sensing result data is time stamped to enable verification of the time of occurrence of the event.

17. A method for processing sensor data of claim 16, wherein the sensing result data is transmitted or received data based on any one of a Modbus communication protocol (Modbus TCP), a DNP 3.0 protocol, or an IEC 61850 protocol.

18. A method for processing sensor data of claim 17, wherein the sensing result data is transmitted and received in accordance with a frame of the Modbus communication protocol (Modbus TCP) comprising a function code region and a data region, wherein the function code region includes an information of a battery cell having a minimum or maximum sensing value stored therein and an information of a location of the battery cell.

19. A method for processing sensor data of claim 18, wherein the data area is allocated bit areas to include 2 bits of bank information, 4 bits of rack information, 5 bits of module information, 4 bits of battery cell information, and 1 bit of error information, respectively.

20. A method for processing sensor data of claim 19, wherein the data area further comprises binary values for the bank information, the rack information, the module information, the battery cell information, and the error information arranged in a row and then replaced by a decimal integer value, wherein the decimal integer value is arranged by raw.
